(19) United States
(12) Patent Application Publication
(10) Pub. No.: US 2024/0367554 A1
(43) Pub. Date: Nov. 7, 2024

(54) FUEL CELL POWER AND BATTERY STATE-OF-CHARGE MANAGEMENT

(71) Applicant: HYZON MOTORS USA INC., Bolingbrook, IL (US)

(72) Inventor: Mark Michelotti, Buffalo Grove, IL (US)

(21) Appl. No.: 18/653,044

(22) Filed: May 2, 2024

Related U.S. Application Data
(60) Provisional application No. 63/500,099, filed on May 4, 2023.

(51) Int. Cl. B60L 58/40; B60L 58/12; G01R 31/382; H01M 8/04537; H01M 8/04858; H01M 10/42; H01M 10/44; H01M 16/00

(52) U.S. Cl. CPC B60L 58/40; B60L 58/12; G01R 31/382; H01M 8/04597; H01M 8/04902; H01M 8/04917; H01M 8/04932; H01M 10/425; H01M 10/446; H01M 16/006; B60L 2240/549; H01M 2010/4271; H01M 2220/20; H01M 2250/20

(57) ABSTRACT

Ways of controlling a fuel cell and a battery are provided that include controlling a current of the battery using a current of the fuel cell and where a target battery state of charge is controlled using an actual state of charge of the battery. Systems and methods may employ an inner loop controller and an outer loop controller. The inner loop controller may be configured to control current of the battery using current of the fuel cell, where the inner loop controller includes an integrating controller operating on a time-averaged basis. The outer loop controller may be configured to control a target battery state of charge using an actual state of charge of the battery, where the outer loop controller includes a proportional controller operating using continuous modulation.

### CROSS-REFERENCE TO RELATED APPLICATIONS

This application claims the benefit of U.S. Provisional Application No. 63/500,099, filed on May 4, 2023. The entire disclosure of the above application is incorporated herein by reference.

### FIELD

The present technology relates to ways of managing fuel cell power and battery state-of-charge, including adaptations for a fuel cell electric vehicle.

### INTRODUCTION

This section provides background information related to the present disclosure which is not necessarily prior art.

A fuel cell electric vehicle (FCEV) includes a fuel cell, sometimes in combination with another electrical power source, to power an onboard electric motor. Fuel cells in vehicles may generate electricity using oxygen sourced from ambient air and hydrogen stored onboard the vehicle. Most fuel cell vehicles are classified as zero-emissions vehicles, emitting only water vapor and heat.

Certain FCEVs may have two electrical power sources: (1) the fuel cell power plant, and (2) a high voltage battery. The fuel cell is typically sized to produce sufficient power to match the maximum continuous electrical power demand of the vehicle, including the onboard electric motor. However, the power demand of the vehicle may change faster than the fuel cell is able to modulate electrical power produced thereby. This issue may be overcome by supplementing the electrical power demand with the high voltage battery, where the battery may respond instantly to changes in power demand, and may also absorb excess power produced by operation of the FCEV; e.g., power generated via regenerative braking.

However, adapting the fuel cell and the battery to meet electrical power demand may present a control problem. In particular, the fuel cell power may be modulated to accomplish two goals. First, the fuel cell power may match the power demand of the vehicle by increasing power as needed, and the fuel cell power may be reduced when not needed; e.g., during braking to maximize a regenerated charge. Optimizing operation of the FCEV may therefore include a reduction of fuel cell power during regenerative braking. Second, the fuel cell power may be modulated to maintain the battery state-of-charge (SOC) within an appropriate range to ensure enough reserve capacity to support transient demands, such as acceleration or regenerative braking, and to maintain the health of the battery by preventing overcharge and overdischarge.

Several strategies may be employed to modulate fuel cell power in the context of a FCEV. One strategy may include load following, where the fuel cell power is modulated to match the vehicle power demand. Variations in SOC are ignored or handled using disablement and derate. Another strategy may include SOC maintenance, where the fuel cell power is modulated only with the goal of maintaining battery SOC at a specific target. Variations in FCEV power demand are ignored and handled by the battery. If the fuel cell power output exceeds the charge limit of the battery, there may be a conflict during braking events-either the battery is overcharged, or the motor produces a positive torque. Yet another strategy involves a hybrid of the first two, where the fuel cell power is modulated first with the goal of maintaining SOC. When vehicle power demand exceeds the fuel cell power produced for SOC maintenance alone, the difference may be added onto the fuel cell power produced in an attempt to meet the total vehicle tractive power demand. However, this approach still does not address the regenerative braking requirements in optimizing operation of the FCEV.

Accordingly, there is a need to modulate fuel cell power to simultaneously maintain SOC at a target level and support the power demand of the vehicle, where the vehicle power demand is supported in both tractive and regenerative directions.

### SUMMARY

The present technology provides articles of manufacture, systems, and processes that relate to managing fuel cell power and battery state-of-charge, including adaptations for a fuel cell electric vehicle including an electric motor and having regenerative braking capability.

Certain embodiments include methods for controlling a fuel cell and a battery. Current of the battery may be controlled using current of the fuel cell, where the current of the battery is controlled by an integral controller on a time-averaged basis. A target battery state of charge may be controlled using an actual state of charge of the battery, where the target battery state of charge is controlled by a controller using modulation, including continuous modulation.

Controlling current of the battery using current of the fuel cell may be performed by feedback from an inner loop. The inner loop may include a target current to battery charge transfer function having an inner loop single integrating controller, a fuel cell current to battery current transfer function, an electric motor, and a battery current to battery charge transfer function. A current from the inner loop single integrating controller and a current from the electric motor may be received by the fuel cell current to battery current transfer function. An output of the fuel cell current to battery current transfer function may be sent to the inner loop single integrating controller and to the battery current to battery charge transfer function.

Controlling the target battery state of charge using the actual state of charge of the battery may be performed by feedback from an outer loop. The outer loop may include an outer loop input, an outer loop proportional controller, and an outer loop output. The outer loop input and an output of the battery current to battery charge transfer function may be sent to the outer loop proportional controller. An output of the outer loop proportional controller may be sent to the inner loop single integrating controller.

Certain embodiments include systems for controlling a fuel cell and a battery, where the system may include an inner loop controller and an outer loop controller. The inner loop controller may be configured to control current of the battery using current of the fuel cell, where the inner loop controller may include an integrating controller operating on a time-averaged basis. The outer loop controller may be configured to control a target battery state of charge using an actual state of charge of the battery, where the outer loop controller may include a proportional controller operating using continuous modulation.

The inner loop controller may be configured to ascertain a current error based upon a target battery current and an actual battery current. The inner loop controller may be configured to output a fuel cell current. The fuel cell current and a motor current may be configured to form a battery current received by the battery.

The outer loop controller may receive a battery state of charge error based upon the target battery state of charge and the actual state of charge of the battery. The outer loop controller may be configured to output the target battery current. The inner loop controller may be nested within operation of the outer loop controller.

In this way, the fuel cell power may be modulated to simultaneously maintain SOC at a target level and support the power demand of the vehicle. The vehicle power demand is supported in both tractive and regenerative directions. The regenerative braking requirement may be accommodated by ramping down fuel cell power in such conditions. The system response, behavior, and tradeoffs of SOC management versus load-following may be easily tuned.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic depiction of a first embodiment of an FCEV management system.

FIG. 2 is a schematic depiction of a second embodiment of an FCEV management system.

FIG. 3 is a schematic depiction of a third embodiment of an FCEV management system.

FIG. 4 is a schematic depiction of a fourth embodiment of an FCEV management system.

FIG. 5 is a graphical depiction of an embodiment of an FCEV management system in operation, where the top panel depicts time(s) versus current (A) for a target battery current along with a measured battery current, and the bottom panel depicts time(s) versus current (A) for a fuel cell along with an electric motor.

FIG. 6 is a graphical depiction of another embodiment of an FCEV management system in operation, where the top panel depicts time(s) versus SOC (A*s) for a target battery SOC along with a measured battery SOC, and the bottom panel depicts time(s) versus current (A) for an electric motor along with a fuel cell.

FIG. 7 is a graphical depiction of yet another embodiment of an FCEV management system in operation, where the top panel depicts time(s) versus SOC (A*s) for a target battery SOC along with a measured battery SOC, and the bottom panel depicts time(s) versus current (A) for an electric motor along with a fuel cell.

FIG. 8 is a schematic depiction of a fifth embodiment of an FCEV management system.

FIG. 9 is a flowchart illustrating a method for controlling a fuel cell and a battery.

### DETAILED DESCRIPTION

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments, including where certain steps can be simultaneously performed, unless expressly stated otherwise. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, 3-9, and so on.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The present technology includes ways to improve control of a fuel cell and a battery, such as fuel cell and battery as part of FCEV including an electric motor. Control of a current of the battery may be based upon a current of the fuel cell, where the current of the battery may be controlled by an integral controller on a time-averaged basis. Control of a target battery state of charge may be based upon an actual state of charge of the battery, where the target battery state of charge is controlled by a controller by modulation, including continuous modulation.

Controlling current of the battery using current of the fuel cell may be performed by feedback from an inner loop that includes a target current to battery charge transfer function. The target current to battery charge transfer function may include an inner loop single integrating controller, a fuel cell current to battery current transfer function, an electric motor, and a battery current to battery charge transfer function. A current from the inner loop single integrating controller and a current from the electric motor may be received by the fuel cell current to battery current transfer function. And an output of the fuel cell current to battery current transfer function may be sent to the inner loop single integrating controller and to the battery current to battery charge transfer function.

Controlling the target battery state of charge using the actual state of charge of the battery may be performed by feedback from an outer loop that includes an outer loop input, an outer loop proportional controller, and an outer loop output. The outer loop input and an output of the battery current to battery charge transfer function may be sent to the outer loop proportional controller. And an output of the outer loop proportional controller may be sent to the inner loop single integrating controller. In this way, the inner loop may be nested within the outer loop.

Systems for controlling a fuel cell and a battery, including in the context of an FCEV having an electric motor, may include an inner loop controller and an outer loop controller. The inner loop controller may be configured to control current of the battery using current of the fuel cell. The inner loop controller may include an integrating controller operating on a time-averaged basis. The outer loop controller may be configured to control a target battery state of charge using an actual state of charge of the battery. The outer loop controller may include a proportional controller operating using continuous modulation.

Additional system aspects include where the inner loop controller may be configured to ascertain a current error based upon a target battery current and an actual battery current. The inner loop controller may be configured to output a fuel cell current. The fuel cell current and a motor current may be configured to form a battery current received by the battery. The outer loop controller may receive a battery state of charge error based upon the target battery state of charge and the actual state of charge of the battery. The outer loop controller may be configured to output the target battery current.

In this way, the present technology provides a control methodology tailored to specific problems and constraints in optimizing operation of the fuel cell and the battery, especially in the context of FCEV providing regenerative braking capability. The inner loop may therefore use a desired battery current as input. A battery current error may be calculated by subtracting a measurement of the battery current. This may be fed to a single-integrating controller which produces as an output the fuel cell current. The outer loop may therefore use a desired battery SOC as input. An SOC error may be calculated by subtracting a measurement or estimate of the battery SOC. This SOC error may be fed to a proportional controller which produces as an output of the desired battery current, which is fed into the inner loop.

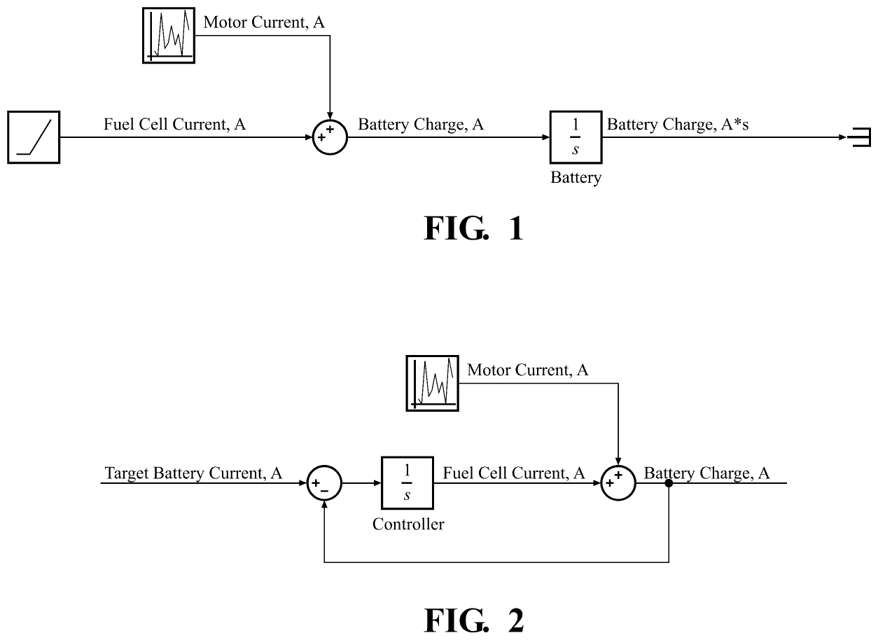

An embodiment of the fuel cell power and battery state-of-charge management technology may include the following aspects. Battery SOC may be a system state selected to control. Fuel cell current output may be selected for control effort. That is, the fuel cell current may be used to control battery SOC. Electric motor current may be used as a disturbance input to the system. Other current sources and sinks on the FCEV may be neglected. Other embodiments may account for one or more additional current sources and/or current sinks. In consideration of these aspects, a simplified system model is represented by FIG. 1. By convention, a positive current acts to charge the battery, and a negative current acts to discharge the battery.

Control of fuel cell power and battery state-of-charge management technology may include two nested feedback loops, designated as an inner loop and an outer loop. Control by the inner loop may use fuel cell current to directly control battery current, as depicted in FIG. 2. The transient response of the fuel cell may normally be slower than the rapidly changing motor current. The effect of the inner loop control may be to turn the instantaneous response of the battery current into a slower first-order response, to better pair with the fuel cell. The present management technology may therefore control the battery current on a time-averaged basis, not an instantaneous basis. Accordingly, integral control may be used, as represented by 1/s in FIGS. 1-4.

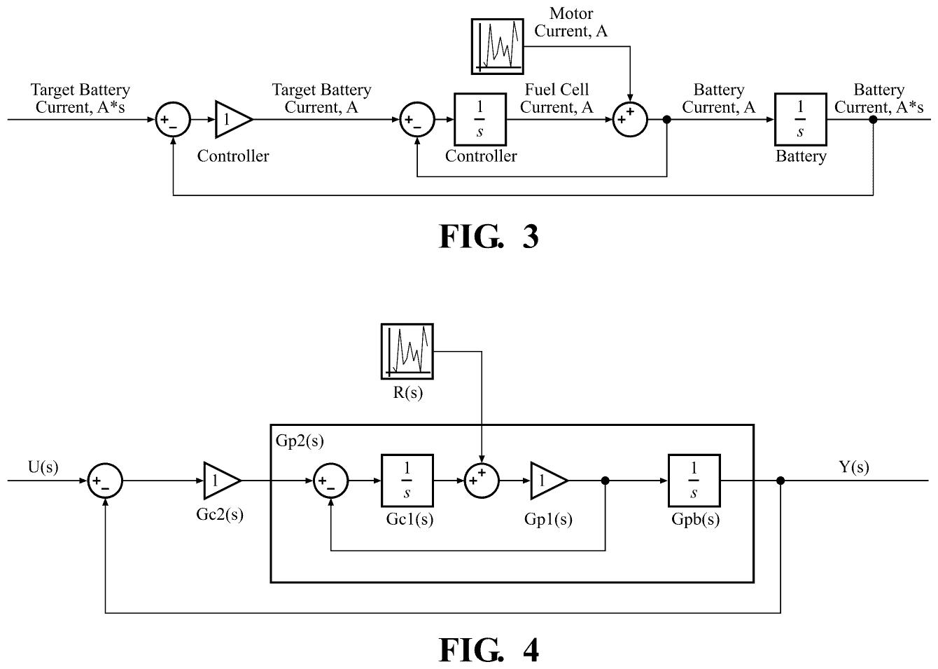

Control by the outer loop may produce a target battery current for control effort, where the target battery current may be passed to the inner loop, as depicted in FIG. 3. A proportional controller may be selected to ensure an appropriate system dynamic response, as further detailed herein. As shown, the actual battery SOC may feed back to the target battery SOC. Examples of the controller may include a proportional-integral-derivative (PID) controller. The controller may include a control loop mechanism employing feedback that may be subjected to continuously modulated control. For example, a PID controller may be used to continuously calculate an error value as the difference between a desired setpoint and a measured process variable and apply a correction based on proportional, integral, and derivative terms (denoted P, I, and D respectively). The controller may also be configured to only use integral gain and/or proportional gain.

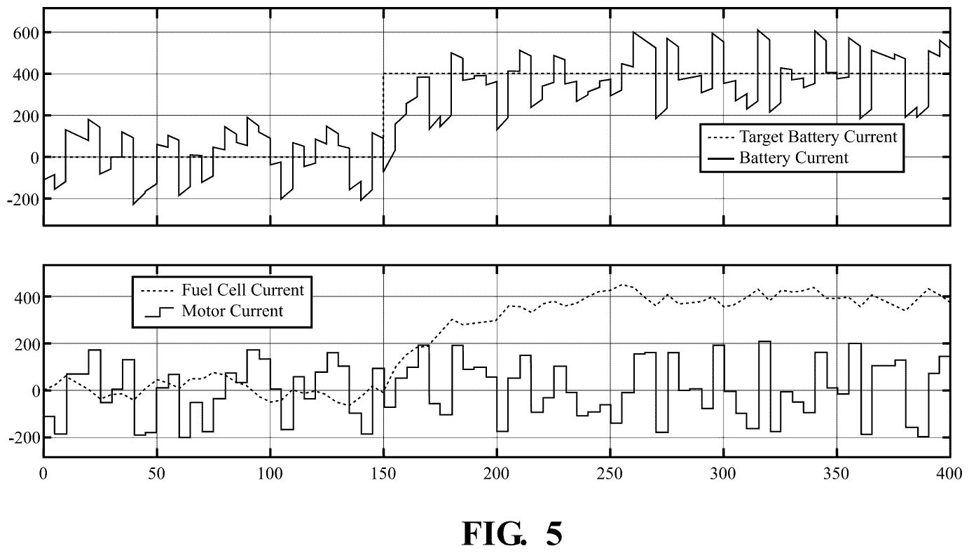

The present fuel cell power and battery state-of-charge management technology may be characterized by a linear analysis of the system. In particular, the embodiment of the system and different signals employed therein may be represented by the schematic depicted in FIG. 4, where the respective parameters are assigned as follows:
G_{P,1}(s)=fuel cell current to battery current transfer function
G_{C,1}(s)=inner loop single integrating controller
G_{P,B}(s)=battery current to battery charge transfer function
G_{P,2}(s)=target current to battery charge transfer function
G_{C,2}(s)=outer loop proportional controller
U(s), Y(s), R(s)=input, output, disturbance

In this way, the inner loop plant may be the battery current, which may be modelled as a unity gain without any dynamic states.

$${G}_{P , 1} ( s ) = 1$$

The closed loop transfer function of the inner loop may be defined as:

$${G}_{1} ( s ) = \frac{{G}_{C , 1} ( s ) {G}_{P , 1} ( s )}{1 + {G}_{C , 1} ( s ) {G}_{P , 1} ( s )}$$

A single-integrating controller may be selected to result in a simple first order response, where K_{I} is a tunable parameter and s/K_{I} is a tunable parameter with respect to the integrator(s), as follows:

$${G}_{1} ( s ) = \frac{1}{\frac{s}{{K}_{1}} + 1}$$

The time constant of the inner loop response may be tuned directly, as it is the inverse of the integral gain. This is an operational aspect of the inner loop—to provide slower, time-averaged control over the battery current, matching the slower time constant of the fuel cell. The disturbance input (e.g., the electric motor current) may also be rejected by the integrating controller, if it is considered as a time-averaged electric motor current. The disturbance may also be accommodated by the control design; however, the controller may be intentionally tuned to move slowly, the disturbance may therefore be considered to not have an appreciable effect and it is sufficient to operate only on the error term.

With reference to FIG. 5, an inner loop simulated result demonstrating the selected behavior is shown. Integral gain (K_{I}) is set to 0.05 to set the time constant at 20 seconds. The disturbance is modeled in the example shown in FIG. 5 as a random number in a range from −200 A to 200 A. The resulting behavior is a slowly modulating control effort that achieves the target battery current on a time-averaged basis.

The outer loop plant may therefore include the inner closed loop transfer function coupled with the battery state of charge, which may be considered a unity gain integrating plant. As described, K_{I} may represent the tunable parameter or gain with respect to the integral controller function.

$${G}_{P , 2} ( s ) = {G}_{1} ( s ) \frac{1}{s} = \frac{1}{\frac{{s}^{2}}{{K}_{1}} + s}$$

A proportional controller may be selected for the outer loop plant, where K_{P} may represent a tunable parameter or gain with respect to the proportional controller function, as follows:

$${G}_{C , 2} ( s ) = {K}_{P}$$

So that the resulting closed loop transfer function may be represented by a well-formed second-order system, as follows:

$${G}_{2} ( s ) = \frac{\frac{{K}_{P}}{\frac{{s}^{2}}{{K}_{1}} + s}}{1 + \frac{{K}_{P}}{\frac{{s}^{2}}{{K}_{I}} + s}} = \frac{{K}_{P}}{\frac{{s}^{2}}{{K}_{1}} + s + {K}_{P}} = \frac{{K}_{P} {K}_{I}}{{s}^{2} + {K}_{I} s + {K}_{P} {K}_{I}}$$

Resulting in final dynamic response parameters for the natural frequency (@n) and a representation of oscillation (¿), as follows:

$${ω}_{n} = \sqrt{{K}_{P} {K}_{I}} , ζ = \frac{{K}_{I}}{2 \sqrt{{K}_{P} {K}_{I}}}$$

The system is stable for all positive gains. The integral gain may be chosen to match the fuel cell dynamics. To avoid overshoot, there may be a maximum limit on the proportional gain:

$${K}_{P} < \frac{{K}_{I}}{4}$$

So, a theoretical limit on the system natural frequency may be set if overshoot is to be avoided:

$${ω}_{n , max} < \frac{{K}_{I}}{2}$$

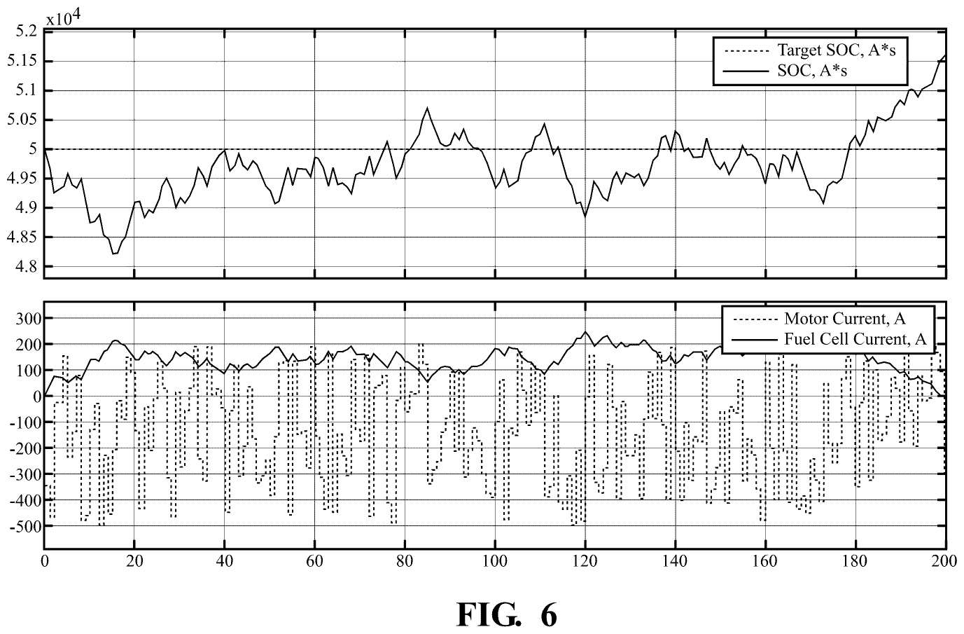

With reference now to FIG. 6, a simulation result for the outer loop SOC control is shown. The Y-axis represents Amp*seconds (A*s), and the X-axis represents seconds(s). In the example shown, the fuel cell current may be limited to only positive values, and the motor current may be biased in the discharge direction.

With respect to implementation of the fuel cell power and battery state-of-charge management technology provided herein, some additional aspects may be considered in the control structure. These include aspects relating to motor load management and fuel cell ramp rate.

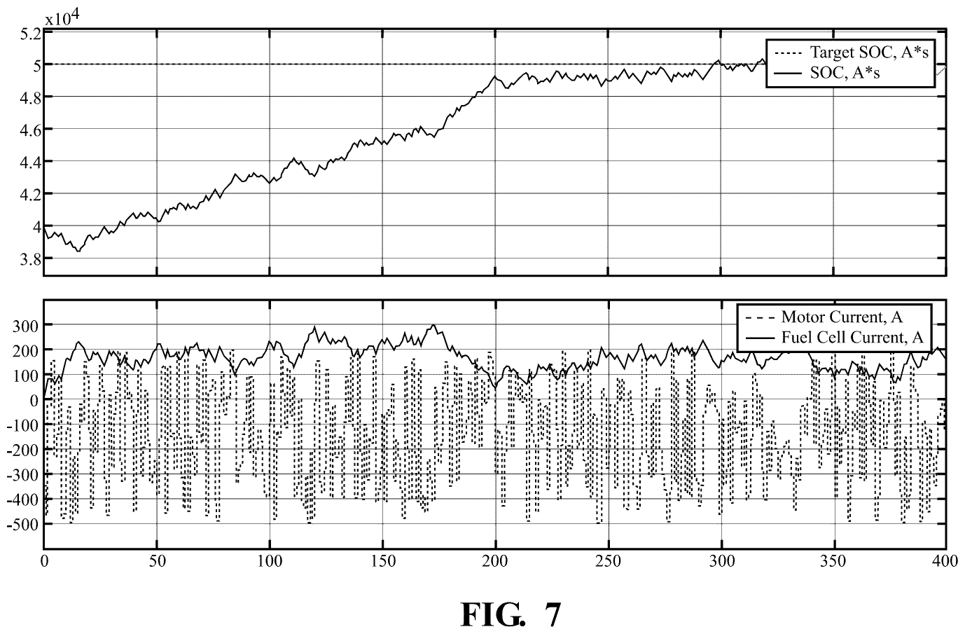

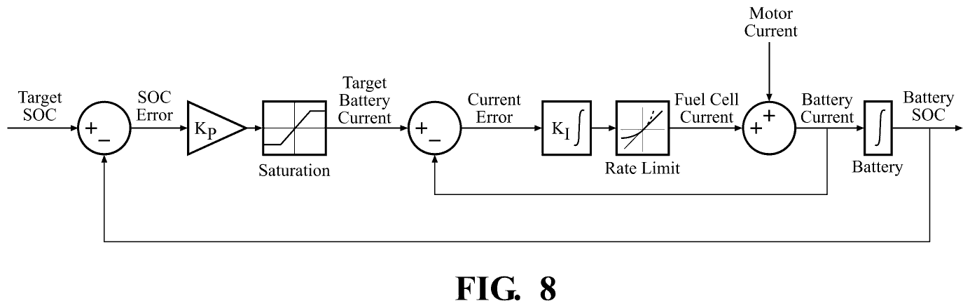

For motor load management, the system may operate to directly trade off SOC management with motor load management. This may be achieved by limiting the target battery current with a saturation-type nonlinearity. Recall that the target battery current may be selected to maintain the battery charge. As such, by only allowing a small target battery current, a larger portion of battery current may be used to achieve load management in the inner loop. For practical implementation, a saturation function may be used after the constant proportional gain. An example embodiment is represented is FIG. 7. In the embodiment shown, +/−50 Amps are allocated to SOC maintenance in the outer loop. The configuration of this system accordingly produces results including: (1) the state of charge recovers to the target SOC, (2) the fuel cell current modulates to support the motor demand, and (3) the fuel cell current demand is slow enough to match the capability of the fuel cell. In this way, for example, the system may recover the SOC while having the capability to cover other inputs, such as current produced from regenerative braking.

For fuel cell ramp rate, the system may be adapted to overcome where the fuel cell current rate-of-change is constrained by the physical limits of the fuel cell system and the impact on the aging rate of the fuel cell system. These considerations are taken into account in the present control system, which results in the inner integral control, and which may be matched with the capabilities of the fuel cell. An upper limit and a lower limit may also be included as a rate limit on the output of this control, since the fuel cell operating limits are to be maintained and are more commonly defined as a maximum ramp rate, not a time constant.

An embodiment of a system for fuel cell power and battery state-of-charge management is shown in FIG. 8.

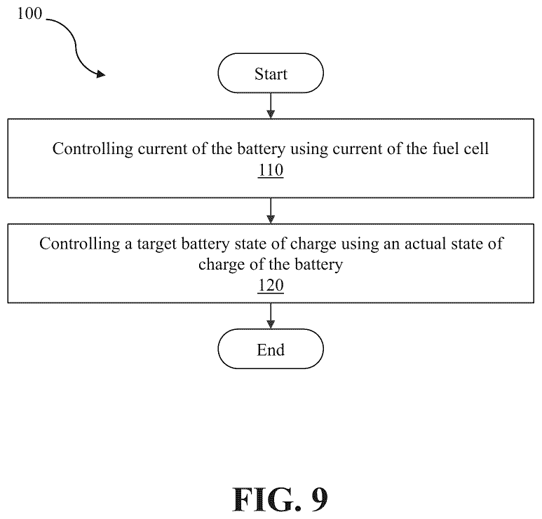

Referring now to FIG. 9, a method 100 method for controlling a fuel cell and a battery is shown therein. In certain embodiments, at step 110, the method 100 may include controlling current of the battery using current of the fuel cell. In the step 120, the method may further include controlling a target battery state of charge using an actual state of charge of the battery. In certain embodiments, the current of the battery may be controlled by an integral controller on a time-averaged basis. In certain embodiments, the target battery state of charge may be controlled by a controller using continuous modulation.

Benefits and advantages of the ways to manage fuel cell power and battery state-of-charge provided by the present technology include a low calibration complexity, where is it possible to base the methods and systems on two parameters; e.g., K_{I} and K_{P}. The present technology may accordingly achieve important aspects in controlling an FCEV. First, the power demand of the vehicle may be matched by increasing power on demand, and reducing power when not needed; e.g. during braking to maximize regenerated charge. Of particular benefit is the ability to reduce fuel cell power during regenerative braking. Second, the battery SOC may be maintained within an appropriate range to ensure enough reserve capacity to support transient demands, such as acceleration or regenerative braking, and to maintain the health of the battery by preventing overcharge and overdischarge.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. Equivalent changes, modifications and variations of some embodiments, materials, compositions and methods may be made within the scope of the present technology, with substantially similar results.

What is claimed is:

1. A method for controlling a fuel cell and a battery, comprising:
controlling current of the battery using current of the fuel cell, wherein the current of the battery is controlled by an integral controller on a time-averaged basis; and
controlling a target battery state of charge using an actual state of charge of the battery, wherein the target battery state of charge is controlled by a controller using continuous modulation.

2. The method of claim 1, wherein controlling current of the battery using current of the fuel cell is performed by feedback from an inner loop, the inner loop including a target current to battery charge transfer function having:
an inner loop single integrating controller;
a fuel cell current to battery current transfer function;
an electric motor; and
a battery current to battery charge transfer function;
wherein:
a current from the inner loop single integrating controller and a current from the electric motor are received by the fuel cell current to battery current transfer function; and
an output of the fuel cell current to battery current transfer function is sent to the inner loop single integrating controller and to the battery current to battery charge transfer function.

3. The method of claim 2, wherein controlling the target battery state of charge using the actual state of charge of the battery is performed by feedback from an outer loop, the outer loop having:
an outer loop input;
an outer loop proportional controller; and
an outer loop output;
wherein:
the outer loop input and an output of the battery current to battery charge transfer function are sent to the outer loop proportional controller; and
an output of the outer loop proportional controller is sent to the inner loop single integrating controller.

4. The method of claim 2, wherein the inner loop comprises an inner loop with a single integrating controller configured to receive a target battery current and an actual battery current, and the single integrating controller outputs a fuel cell current based on a difference between the target battery current and the actual battery current.

5. The method of claim 4, wherein the inner loop further comprises a fuel cell current to battery current transfer function that receives the fuel cell current and a motor current, and the single integrating controller outputs a modified battery current to a battery current to battery charge transfer function.

6. The method of claim 5, wherein the battery current to battery charge transfer function outputs a measured battery state of charge, and the measured battery state of charge is used to determine the actual state of charge of the battery.

7. The method of claim 1, further comprising an outer loop with a proportional controller that receives a target battery state of charge and the actual state of charge of the battery, and the proportional controller outputs a target battery current based on a difference between the target battery state of charge and the actual state of charge.

8. The method of claim 7, wherein the outer loop proportional controller output is used as an input to an inner loop single integrating controller to modulate the fuel cell current.

9. The method of claim 8, wherein the outer loop is configured to adjust the target battery current based on a saturation-type nonlinearity to regulate a battery state of charge maintenance and a motor load management.

10. The method of claim 1, wherein the fuel cell and the battery are components of a fuel cell electric vehicle (FCEV), and wherein the method further comprises modulating a fuel cell power to support vehicle power demand in both tractive and regenerative braking modes.

11. The method of claim 1, wherein controlling current of the battery using current of the fuel cell is performed by feedback from an inner loop, the inner loop including a target current to battery charge transfer function having:
an inner loop single integrating controller;
a fuel cell current to battery current transfer function;
an electric motor; and
a battery current to battery charge transfer function;
wherein:
a current from the inner loop single integrating controller and a current from the electric motor are received by the fuel cell current to battery current transfer function;
an output of the fuel cell current to battery current transfer function is sent to the inner loop single integrating controller and to the battery current to battery charge transfer function;
the inner loop includes an inner loop with a single integrating controller configured to receive a target battery current and an actual battery current, and the single integrating controller outputs a fuel cell current based on a difference between the target battery current and the actual battery current;
the inner loop further includes a fuel cell current to battery current transfer function that receives the fuel cell current and a motor current, and the single integrating controller outputs a modified battery current to a battery current to battery charge transfer function;
the battery current to battery charge transfer function outputs a measured battery state of charge, and the measured battery state of charge is used to determine the actual state of charge of the battery.

12. A system for controlling a fuel cell and a battery, comprising:
an inner loop controller configured to control current of the battery using current of the fuel cell, wherein the inner loop controller includes an integrating controller operating on a time-averaged basis; and
an outer loop controller configured to control a target battery state of charge using an actual state of charge of the battery, wherein the outer loop controller includes a proportional controller operating using continuous modulation.

13. The system of claim 12, wherein:
the inner loop controller is configured to ascertain a current error based upon a target battery current and an actual battery current, the inner loop controller is configured to output a fuel cell current, and the fuel cell current and a motor current are configured to form a battery current received by the battery; and
the outer loop controller receives a battery state of charge error based upon the target battery state of charge and the actual state of charge of the battery, and the outer loop controller is configured to output the target battery current.

14. The system of claim 13, wherein the inner loop controller further comprises a fuel cell current to battery current transfer function that is configured to receive the fuel cell current and a motor current, and a single integrating controller is configured to output a modified battery current to a battery current to battery charge transfer function.

15. The system of claim 14, wherein the battery current to battery charge transfer function is configured to output a measured battery state of charge, and the measured battery state of charge is used by the outer loop controller to determine the actual state of charge of the battery.

16. The system of claim 15, wherein the outer loop controller is further configured to receive a battery state of charge error based on a difference between the target battery state of charge and the actual state of charge, and to output a modified target battery current to the inner loop controller.

17. The system of claim 16, wherein the outer loop controller includes a saturation function to limit the target battery current to manage a trade-off between battery state of charge maintenance and motor load management.

18. The system of claim 17, wherein the saturation function is configured to allocate a predetermined amount of the battery current for state of charge maintenance, allowing a remainder for motor load management.

19. The system of claim 18, wherein the inner loop controller includes a rate limiter to constrain a rate of change of the fuel cell current to within predefined operational limits of the fuel cell system.
